(19) United States
(12) Patent Application Publication
(10) Pub. No.: US 2026/0043709 A1
(43) Pub. Date: Feb. 12, 2026

(54) DIAGNOSTIC SYSTEM AND DIAGNOSTIC METHOD FOR DETERMINING A STATE OF A PRESSURIZED GAS TANK MADE OF FIBER-REINFORCED PLASTIC

(71) Applicant: Robert Bosch GmbH, Stuttgart (DE)

(72) Inventor: Alexander Elter, Oftersheim (DE)

(21) Appl. No.: 19/101,973

(22) PCT Filed: Jul. 27, 2023
(86) PCT No.: PCT/EP2023/070841

§ 371 Date: Feb. 7, 2025

(30) Foreign Application Priority Data
Aug. 16, 2022 (DE) 10 2022 208 495.0

(51) Int. Cl. G01M 7/02; G06F 30/27

(52) U.S. Cl. CPC G01M 7/025; G06F 30/27

(57) ABSTRACT

The present invention relates to a diagnostic system (103) for determining a state of a pressurized gas tank (101) made of fiber-reinforced plastic.

The diagnostic system (103) comprises an excitation element (105), a sensor (109) and an evaluation unit (113), wherein the excitation element (105) is configured to introduce sound waves into the pressurized gas tank (101), wherein the sensor (109) is configured to sense sound waves conducted into the pressurized gas tank (101) by the excitation element (105), and wherein the evaluation unit (113) is configured to associate respective measured values determined by the sensor (109) with a characteristic value, describing a state of the pressurized gas tank (101) and outputting the associated characteristic on an output unit.

### BACKGROUND

The presented invention relates to a diagnostic system and a diagnostic method for determining a state of a pressurized gas tank made of fiber-reinforced plastic, as well as a tank system having the presented diagnostic system.

Pressurized gas tanks for storing fluids, such as hydrogen, are often made of fiber-reinforced plastic, i.e. a matrix of, for example, a plastic with fibers embedded therein.

It has been shown that faulty pressurized gas tanks are typically caused by two damage mechanisms. The first of these is a fiber break in which the fibers are damaged by mechanical stress, for example, such that the pressurized gas tank typically leaks and becomes unusable. On the other hand, intermediate fiber fractures are known in which only the plastic lying between the fibers is damaged, thereby only reducing the stiffness of the pressurized gas tank, but usually not causing a leak. While fiber breaks usually only occurs when the tank bursts, an intermediate fiber fracture can occur before this, e.g., due to fatigue, without affecting the structural integrity of the tank. At the same time, intermediate fiber fractures can lead to cracks in the plastic matrix and, correspondingly, leaks in the tank. In both cases, the service life and durability of the tank are reduced.

### SUMMARY

A diagnostic system, a tank system and a diagnostic method for determining a state of a pressurized gas tank made of fiber-reinforced plastic are presented in the context of the presented invention. Further features and details of the invention arise from the respective dependent claims, the description, and the drawings. In this context, features and details described in connection with the diagnostic method according to the invention clearly also apply in connection with the diagnostic system and the tank system according to the invention, and respectively vice versa, so that mutual reference to the individual aspects of the invention always is or can be made with respect to the disclosure.

The invention presented serves in particular to detect that a faulty pressurized gas tank is faulty.

Thus, according to a first aspect of the invention presented, a diagnostic system for determining a state of a pressurized gas tank made of fiber-reinforced plastic is presented. The diagnostic system comprises an excitation element, a sensor, and an evaluation unit.

The excitation element is configured to introduce sound waves into the pressurized gas tank.

The sensor is configured to sense sound waves conducted into the pressurized gas tank by the excitation element.

The evaluation unit is configured to associate respective measured values determined by the sensor with a characteristic value that describes a state of the pressurized gas tank and output the associated characteristic value on an output unit.

In the context of the invention presented, an excitation element is to be understood as a component that is capable of introducing sound waves into a pressurized gas tank body, in particular as structure-borne sound. An excitation element may be, for example, an ultrasonic transducer.

In the context of the invention presented, a sensor is to be understood as a component that is capable of sensing sound waves, in particular structure-borne sound, from a pressurized gas tank body. A sensor may be, for example, a knock sensor and/or a MEMS.

In the context of the invention presented, an evaluation unit is understood to mean a computing unit, in particular a control device or a processor, or any other programmable circuit.

The invention presented is based on the principle that a change in sound waves introduced into a pressurized gas tank, i.e. into the housing body or the support structure of a pressurized gas tank, is detected and a state of the pressurized gas tank is determined based on the change. The determined state is described via a characteristic value and output on an output unit, such as a display or a memory. The change in the tank is determined, for example, by correlating the recorded signal and, for example, an abnormality detection with general mathematical methods of machine learning or statistics.

Because sound waves in a fiber-plastic composite with existing intermediate fiber fractures or fiber breaks travel or behave differently than in a composite with non-broken fibers or undamaged intermediate fiber material, a behavior, in particular a change in the sound waves, can be used to infer a state of the composite.

The presented diagnostic system may be reversibly disposed on a pressurized gas tank or fixedly connected to the pressurized gas tank. Further, the presented diagnostic system may be configured to perform the presented diagnostic method on a respective pressurized gas tank one or multiple times. Accordingly, the diagnostic system may be used, for example, to conduct diagnostics on pressurized gas tanks in a production line or to conduct diagnostics on a pressurized gas tank over time in, for example, a vehicle. In particular, the presented diagnostic system may be configured to issue a warning message when a faulty pressurized gas tank is detected or when respective readings are associated with a characteristic value corresponding to a faulty state. Accordingly, the characteristic value corresponding to a faulty state may comprise a warning message or may be a warning message.

It may be contemplated that the excitation element is configured to introduce structure-borne sound into the pressurized gas tank and the sensor is configured to sense structure-borne sound emitted by the pressurized gas tank.

To introduce structure-borne sound into a pressurized gas tank or a pressurized gas tank housing, the excitation element may comprise a contact element, such as a vibration element, that repeatedly contacts the pressurized gas tank, for example taps it, and, as a result, generates sound waves in or directs sound waves through the pressurized gas tank.

For example, a microphone or a knock sensor may be used to capture structure-borne sound passing through a pressurized gas tank.

It may further be contemplated that the evaluation unit is configured to execute a machine learner trained to associate respective measured values determined by the sensor with a first characteristic value or a second characteristic value, wherein the first characteristic value corresponds to a fault-free state and the second characteristic value corresponds to a faulty state.

By means of a machine learner, such as an artificial neural network, a signal determined or measured by the sensor provided according to the invention can be automatically assigned a corresponding characteristic value, such as “faulty” or “fault-free”. Accordingly, the machine learner may classify a particular signal. For this purpose, the evaluation unit can provide the signal directly to the machine learner as an input signal or pre-process it by a number of pre-processing steps, such as low-pass filters, and then provide them to the machine learner as an input signal.

It may be contemplated that the machine learner may be trained on the basis of fault-free and/or faulty pressurized gas tanks and a provided ground truth.

By training the machine learner based on fault-free and/or faulty pressurized gas tanks and/or a provided ground truth, respective detection limits of the machine learner can be set.

For example, it can be provided that the machine learner is only trained using fault-free pressurized gas tanks in a so-called “unsupervised approach”, so that, if a deviating signal occurs, the machine learner automatically assigns a corresponding pressurized gas tank a characteristic value that describes a faulty state without having a model of a faulty state.

Alternatively, it may be contemplated that the machine learner is trained in a so-called “supervised approach” with a ground truth, a number of fault-free pressurized gas tanks, and a number of faulty pressurized gas tanks, such that the machine learner develops a model of fault-free pressurized gas tanks and faulty pressurized gas tanks. In this case, a tolerance in the quality of the pressurized gas tanks can be determined by a corresponding ground truth, so that the machine learner does not yet carry out an assignment to a characteristic value that describes an incorrect state even in the case of a slight deviation of a respective measurement signal from an expected signal.

It may further be contemplated that the machine learner is pre-trained on differently structured material samples and a ground truth to associate respective material samples to a first class representing a faulty state or a second class representing a fault-free state and the machine learner is validated by measured values from at least one pressurized gas tank.

By means of so-called “pre-training” or so-called “transfer learning” using material samples, using a high number of pressurized gas tanks to train the machine learner is not necessary, because structural properties of faulty or fault-free pressurized gas tanks can be depicted in a controlled manner by the material samples. By means of validation based on measurement data of at least one complete pressurized gas tank, the quality of a transmission of a training based on material samples to a complete pressurized gas tank can be determined or evaluated.

It may further be contemplated that that the evaluation unit is configured to execute a mathematical simulation model that simulates an intermediate fiber fracture strain and/or a load on components of an inner lining of a respective pressurized gas tank based on respective measured values determined by the sensor and determines a leakage caused by the simulated intermediate fiber fracture strain and/or simulated load on the components of the inner lining, and the evaluation unit is further configured to assign a corresponding characteristic value to the pressurized gas tank using the leakage determined by the mathematical simulation model as the input signal for the machine learner.

A mathematical simulation model that associates a deviation in a measured signal with a leakage or simulates the extent to which the deviation leads to a leakage or not can provide an input signal or so-called “feature,” which can be used by the machine learner provided according to the invention, for example, for training. In particular, the simulation model can include a database provided to the simulation model by experiments on pressurized gas tanks by means of, for example, increasing interpolation such that a number of pressurized gas tanks required to determine a database for training the machine learner are minimized.

According to a second aspect, the invention presented relates to a tank system. The tank system includes a pressurized gas tank of fiber-reinforced plastic and a possible embodiment of the presented diagnostic system.

For example, the diagnostic system may be disposed on the pressurized gas tank or in an area around the pressurized gas tank such that the excitation element may excite the pressurized gas tank and the sensor may sense corresponding sound waves.

It may be contemplated that the excitation element is disposed at a first end of the pressurized gas tank and the sensor is disposed at a second end of the pressurized gas tank opposite the first end.

An opposing arrangement of excitation element and sensor at respective ends of a pressurized gas tank causes sound waves introduced by the excitation element into the pressurized gas tank to pass through the entire pressurized gas tank and across an entire length of the pressurized gas tank, such that the entire shell structure of the pressurized gas tank is checked for changes and/or faults. A dampening rubber suspension may be provided in order to attenuate parasitic paths.

According to a third aspect, the invention presented relates to a diagnostic method for determining a state of a pressurized gas tank made of fiber-reinforced plastic.

The diagnostic method includes introducing sound waves into the pressurized gas tank by means of an excitation element, sensing sound waves conducted into the pressurized gas tank by the excitation element by means of a sensor, associating a characteristic value with respective measured values determined by the sensor, wherein the characteristic value describes a state of the pressurized gas tank, and outputting the characteristic value on an output unit.

The presented diagnostic system is used in particular to perform the presented diagnostic method.

It may be contemplated that the diagnostic method further comprises training a machine learner to associate a characteristic value with respective measured values determined by the sensor, wherein the training comprises training the machine learner on the basis of fault-free and/or faulty pressurized gas tanks and a provided ground truth.

By using a ground truth, i.e. a mapping provided by, for example, a user to a respective characteristic value, the machine learner can successively adjust its internal mathematical model in an iterative method until this ultimately leads to a mapping of the training data to the respective characteristic values that corresponds best to the ground truth.

It may further be contemplated that that the diagnostic method comprises executing a mathematical model that determines, based on measured values determined by the sensor, an intermediate fiber fracture strain and/or a load on components of an inner lining of a respective pressurized gas tank and a leakage caused by the simulated intermediate fiber fracture strain and/or a simulated load on the components of the inner lining, and associating the characteristic value with the pressurized gas tank by means of the machine learner, wherein the determined leakage is used by the machine learner as the input signal.

Further advantages, features, and details of the invention arise from the following description, in which exemplary embodiments of the invention are described in detail with reference to the drawings. In this context, the features mentioned in the claims and in the description can each be essential to the invention individually or in any combination.

### BRIEF DESCRIPTION OF THE DRAWINGS

Shown are:

FIG. 1 a diagram of a possible embodiment of the tank system presented with a possible configuration of the diagnostic system presented,

FIG. 2 a diagram of a possible embodiment of the diagnostic method presented.

FIG. 3 a flow chart of a training of a machine learner to perform a possible embodiment of the diagnostic method presented.

### DETAILED DESCRIPTION

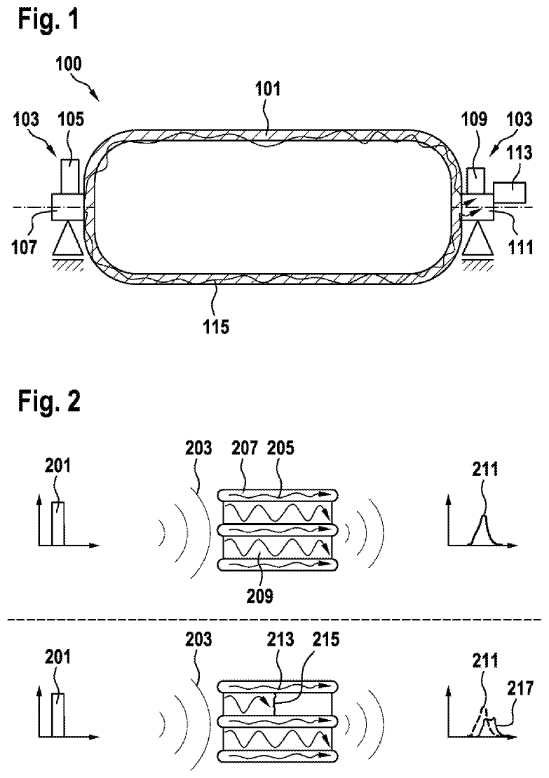

FIG. 1 shows a tank system 100. The tank system 100 comprises a pressurized gas tank 101 and a diagnostic system 103.

The diagnostic system 103 comprises an excitation element 105 in the form of an ultrasonic transducer disposed at a mounting point 107 of the pressurized gas tank 101, a sensor 109 disposed at a mounting point 111 of the pressurized gas tank 101, and an evaluation unit 113 communicatively connected to the excitation element 105 and the sensor 109.

Sound waves 115 introduced into the pressurized gas tank 101 by the excitation element 105 travel along a transport path along the pressurized gas tank to the sensor 109 and are sensed by the sensor 109. A measurement signal of the sensor 109 is transmitted to the evaluation unit 113.

The evaluation unit assigns a characteristic value, such as “fault-free” or “faulty” by means of a machine learner, for example in the form of an artificial neural network, and outputs the characteristic value on an output unit which is not shown, for example as a warning message.

In FIG. 2, the operation described in FIG. 1 is shown in detail. An excitation pulse 201 generates a sound wave 203 that is introduced into a composite 205 of fibers 207, such as, for example, carbon fibers and plastic 209, such as epoxy resin, of a pressurized gas tank; in a fault-free composite 205, the sound wave 203 may travel through the plastic 209 substantially unhindered and may cause a characteristic measurement signal 211.

In a faulty composite 213, the sound wave 203 is prevented from or delayed while traveling through the compound 213, for example, by a crack 215, such that a measurement signal 217 different from the characteristic measurement signal 211 is generated.

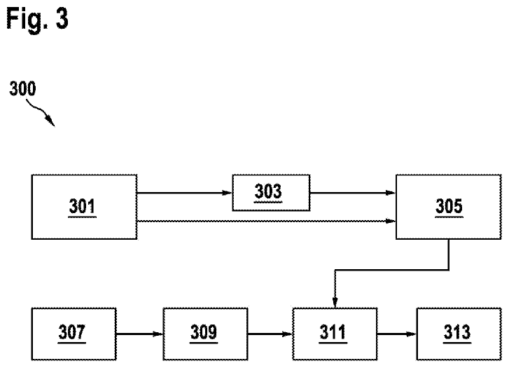

In FIG. 3, a method 300 for training a first machine learner is shown. The method 300 starts with a classification process 301 in which the first machine learner is trained on material samples with different structural characteristics. Measured values determined by the material samples can be used to form input data or so-called “features” in a pre-processing step 303, which is provided to the first machine learner for a classification process in which the first machine learner assigns respective material samples to a characteristic value “faulty” or a characteristic value “fault-free”. A correspondingly trained first machine learner is cached in a storage step 305 to provide this for a transfer step 311. By using material samples to train the first machine learner, the use of pressurized gas tanks can be minimized.

Alternatively, a regression may be performed on the basis of the measured values which mathematically depicts a plurality of corresponding intermediate states.

Further, the method 300 comprises an additional training step 307 in which a further machine learner is trained on the basis of measured values determined using complete pressurized gas tanks.

In order to minimize a number of pressurized gas tanks to be used for the further training step 307, measured values determined in an optional modeling step 309 can be used in the further training step 307 to form a mathematical simulation model that comprises an intermediate fiber fracture strain or intermediate fiber fracture load of a material sample, in particular a tank, and allocates it a value for a corresponding leakage. Accordingly, a database that depicts a behavior of complete pressurized gas tanks can be enlarged by the simulation model by interpolating, for example, between respective measured values or determining additional values.

In the transfer step 311, a mathematical model underlying the first machine learner is merged with a mathematical model underlying the further machine learner, or the first machine learner is trained on values determined by the simulation model, such that the first machine learner is validated by readings from complete pressurized gas tanks.

In an application step 313, the final mathematical model is employed by means of the first machine learner in a diagnostic system for diagnosing a state or a so-called “state of health” of a pressurized gas tank.

1. A diagnostic system (103) for determining a state of a pressurized gas tank (101) made of fiber-reinforced plastic,
wherein the diagnostic system (103) comprises:
an excitation element (105),
a sensor (109),
an evaluation unit (113),
wherein the excitation element (105) is configured to introduce sound waves into the pressurized gas tank (101),
wherein the sensor (109) is configured to sense sound waves conducted into the pressurized gas tank (101) by the excitation element (105),
wherein the evaluation unit (113) is configured to associate respective measured values determined by the sensor (109) with a characteristic value that describes a state of the pressurized gas tank (101) and to output the associated characteristic value on an output unit.

2. The diagnostic system (103) according to claim 1,
wherein
the excitation element (105) is configured to introduce structure-borne sound into the pressurized gas tank (101) and the sensor (109) is configured to sense structure-borne sound emitted by the pressurized gas tank (101).

3. The diagnostic system (103) according to claim 1,
wherein
the evaluation unit (113) is configured to execute a machine learner trained to associate respective measured values determined by the sensor (109) with a first characteristic value or a second characteristic value, wherein the first characteristic value corresponds to a fault-free state and the second characteristic value corresponds to a faulty state.

4. The diagnostic system (103) according to claim 3,
wherein
the machine learner is trained on fault-free and/or faulty pressurized gas tanks (101) and/or a provided ground truth.

5. The diagnostic system (103) according to claim 4,
wherein
the machine learner is pre-trained by means of differently structured material samples and a ground truth to associate respective material samples to a first class representing a faulty condition or a second class representing a fault-free condition and the machine learner is validated by means of measured values of at least one pressurized gas tank.

6. The diagnostic system (103) according to claim 4,
wherein
the evaluation unit (113) is configured to execute a mathematical simulation model that simulates an intermediate fiber break strain and/or a load of an inner chuck of a respective pressurized gas tank (101) determined from respective measured values determined by the sensor (109) and determines a leakage caused by the simulated intermediate fiber break strain and/or the simulated load of the inner chuck, and
the evaluation unit (113) is further configured to associate a corresponding characteristic value with the pressurized gas tank (101) as an input signal for the machine learner based on values determined by the mathematical simulation model.

7. A tank system (100),
wherein the tank system comprises:
a pressurized gas tank (101) made of fiber-reinforced plastic,
a diagnostic system (103) according to claim 1.

8. The tank system (100) according to claim 7,
wherein
the excitation element (105) is disposed at a first end of the pressurized gas tank (101) and the sensor (109) is disposed at a second end of the pressurized gas tank (101) opposite the first end.

9. A diagnostic method for determining a state of a pressurized gas tank (101) made of fiber-reinforced plastic,
wherein the diagnostic method comprises:
introducing sound waves into the pressurized gas tank (101) by means of an excitation element (105),
sensing sound waves conducted into the pressurized gas tank (101) by the excitation element (105) by means of a sensor (109),
associating a characteristic value with respective measured values determined by the sensor (109),
wherein the characteristic value describes a state of the pressurized gas tank (101),
outputting the characteristic value on an output unit.

10. The diagnostic method according to claim 9,
wherein
the diagnostic method further comprises:
training (300) a machine learner to associate a characteristic value with respective measured values determined by the sensor (109),
wherein the training (300) comprises the machine learner being trained on fault-free and/or faulty pressurized gas tanks and a provided ground truth.

11. The diagnostic method according to claim 10,
wherein
the diagnostic method comprises:
executing (303) a mathematical simulation model that determines an intermediate fiber break strain and/or a load of an inner chuck of a respective pressurized gas tank (101) and a leakage caused by the simulated intermediate fiber break strain and/or simulated load of the inner chuck based on measured values determined by the sensor (109), and
associating (313) the characteristic value with the pressurized gas tank (101) by means of the machine learner, wherein the determined leakage is used as the input signal by the machine learner.
